(19) United States
(12) Patent Application Publication
(10) Pub. No.: US 2024/0105473 A1
(43) Pub. Date: Mar. 28, 2024

(54) Optical Annealing Apparatus And Method For Forming Semiconductor Structure

(71) Applicant: Shanghai Huahong Grace Semiconductor Manufacturing Corporation, Pudong (CN)

(72) Inventor: Lei WANG, Shanghai (CN)

(73) Assignee: Shanghai Huahong Grace Semiconductor Manufacturing Corporation, Pudong (CN)

(21) Appl. No.: 18/319,321

(22) Filed: May 17, 2023

(30) Foreign Application Priority Data
Sep. 23, 2022 (CN) 202211166803.5

(51) Int. Cl. H01L 21/67; H01L 21/265; H01L 21/324

(52) U.S. Cl. CPC H01L 21/67115; H01L 21/265; H01L 21/324

(57) ABSTRACT

The present disclosure provides an optical annealing apparatus and a method for forming a semiconductor structure. The optical annealing apparatus includes: a platform for carrying a wafer; a light source for emitting an annealing light to the wafer; and a mask layer disposed between the platform and the light source, wherein the mask layer has a pattern opening for allowing the annealing light to pass through, and the annealing light passing through the pattern opening is used for annealing a partial area of the wafer. The optical annealing apparatus and the method for forming the semiconductor structure can simplify the formation process of an ion doped region and reduces costs.

### CROSS-REFERENCE TO RELATED APPLICATIONS

The application claims the benefit of priority to Chinese patent application No. 202211166803.5, filed on Sep. 23, 2022, the entire disclosure of which is incorporated herein by reference.

### TECHNICAL FIELD

The present disclosure relates to the technical field of semiconductors, and more particularly to an optical annealing apparatus and a method for forming a semiconductor structure.

### BACKGROUND

In a semiconductor device, an ion doped regions is a common part of a device structure. For example, the ion doped region is widely used in an insulated gate bipolar transistor (IGBT), a field effect transistor, or a contact image sensor (CIS).

In existing process, a common method for forming the ion doped region includes: forming a photolithography pattern structure to define a range of ion implantation before ion implantation; performing an ion implantation using the photolithography pattern structure as a mask; activating doped ions through an annealing process to ultimately form the ion doped region.

However, the existing process for forming the ion doped region is complex and costly.

### SUMMARY

The embodiments of the present disclosure provide an optical annealing apparatus and a method for forming a semiconductor structure, in order to simplify the formation process of ion doped regions and reduce costs.

According to an aspect of the present disclosure, an optical annealing apparatus includes: a platform for carrying a wafer; a light source for emitting an annealing light to the wafer; and a mask layer disposed between the platform and the light source, wherein the mask layer has a pattern opening for allowing the annealing light to pass through, and the annealing light passing through the pattern opening is used for annealing a partial area of the wafer.

According to some embodiments, the annealing light emitted by the light source includes laser.

According to some embodiments, the laser has a wavelength ranging from 300 microns to 600 microns.

According to some embodiments, the mask layer includes a mask substrate and a plurality of mask pattern structures disposed on the mask substrate, and the pattern opening is formed between the plurality of mask pattern structures, wherein the mask substrate is made of a light transmitting material, and the plurality of mask pattern structures are made of an opaque material.

According to some embodiments, the mask substrate is made of quartz.

According to some embodiments, the plurality of mask pattern structures are made of one or more selected from a group consisting of chromium, molybdenum, selenium, silicon, aluminum and copper.

According to some embodiments, the optical annealing apparatus further includes an optical system for adjusting and controlling parameters of the light source.

According to some embodiments, the optical annealing apparatus further includes a transporting system for transporting the wafer to the platform or transporting the wafer from the platform.

According to some embodiments, the optical annealing apparatus further includes a mask carrying component for adjusting a relative position between the mask layer and the wafer.

According to another aspect of the present disclosure, a method for forming a semiconductor structure includes: providing an optical annealing apparatus, wherein the optical annealing apparatus includes: a platform for carrying a wafer; a light source for emitting an annealing light to the wafer; and a mask layer disposed between the platform and the light source, wherein the mask layer has a pattern opening for allowing the annealing light to pass through, and the annealing light passing through the pattern opening is used for annealing a partial area of the wafer; providing the wafer; placing the wafer on the platform; performing an ion implantation on the wafer to form an initial ion implantation region in the wafer; and annealing a portion of the initial ion implantation region to form an ion doped region in the portion of the initial ion implantation region by the optical annealing apparatus.

According to some embodiments, the wafer has a thickness ranging from 50 microns to 200 microns.

According to some embodiments, the pattern opening has a pattern corresponding to a pattern of the ion doped region.

According to some embodiments, the wafer has a first surface and a second surface opposite to each other, the first surface has a first device region, and the second surface faces the light source.

In the optical annealing apparatus provided by the embodiments of the present disclosure, the mask layer is disposed between the platform and the light source, the mask layer has a pattern opening for allowing the annealing light to pass through, and the annealing light passing through the pattern opening is used for annealing a partial area of the wafer. Due to the presence of the mask layer, the light from the light source can selectively pass through the mask layer to reach the platform, and the pattern of the pattern opening can define an effective area of annealing treatment so as to control the formation of corresponding structural pattern in the wafer on the platform. Moreover, since the optical annealing apparatus provided by the embodiments of the present disclosure can control the light from the light source to selectively pass through the mask layer so as to control the formation of corresponding structural patterns in the wafer on the platform, the process of defining pattern structures through photolithography process can be eliminated, which can save process steps and significantly reduce costs. In addition, since the effective area of the annealing treatment can be controlled through the pattern opening of the mask layer, other areas of the wafer that do not require annealing treatment are blocked. Therefore, there is no need to adjust the light source to ensure annealing uniformity on each area of the wafer, which can simplify an adjustment process for adjusting the light source during the annealing treatment process and reduce the process difficulty.

In the method for forming the semiconductor structure provided by the embodiments of the present disclosure, the mask layer is disposed between the platform and the light source of the optical annealing apparatus, the mask layer has a pattern opening for allowing the annealing light to pass through, and the annealing light passing through the pattern opening is used for annealing a partial area of the wafer. Due to the presence of the mask layer, the light from the light source can selectively pass through the mask layer to reach the wafer on the platform, and the pattern of the pattern opening can define an effective area of annealing treatment so as to control the pattern of the ion doped region in the wafer. Moreover, since the mask layer can control the light from the light source to selectively pass through the mask layer so as to control the pattern of the ion doped region in the wafer, the process of defining the pattern of the ion doped region through photolithography process in traditional ion implantation processes can be eliminated, which can save process steps and significantly reduce process costs, especially in the formation of the ion doped region on a back side of the wafer. In addition, since the effective area of the annealing treatment can be controlled through the pattern opening of the mask layer, other areas of the wafer that do not require annealing treatment are blocked. Therefore, there is no need to adjust the light source to ensure annealing uniformity on each area of the wafer, which can simplify an adjustment process for adjusting the light source during the annealing treatment process and reduce the process difficulty.

### BRIEF DESCRIPTION OF THE DRAWINGS

FIG. 1 is a schematic structural sectional view of an optical annealing apparatus according to an embodiment of the present disclosure; and

FIGS. 2 to 5 are schematic structural sectional views illustrating steps of a method for forming a semiconductor structure according to an embodiment of the present disclosure.

### DETAILED DESCRIPTION

As described in the background, the existing process for forming the ion doped region is complex and costly.

Specifically, a method for forming the ion doped region includes: forming a photolithography pattern structure to define a range of ion implantation before ion implantation; performing an ion implantation using the photolithography pattern structure as a mask; activating doped ions through an annealing process to ultimately form the ion doped region.

However, in the above method, the method for forming the photolithography pattern structure is usually more complex and costly. At the same time, in many devices, the thickness of the wafer is becoming thinner, and the process of patterning and ion implantation on the wafer usually requires specialized patterning equipment and processes for the wafer. Especially when forming a device structure on a back side of the wafer, the difficulty of patterning and forming the ion doped region is greater, and the cost is higher. Therefore, there is an urgent need for a method and apparatus that can simplify process steps of forming the ion doped region and reduce process costs.

An embodiment of the present disclosure provides an optical annealing apparatus, wherein a mask layer is disposed between a platform and a light source, the mask layer has a pattern opening for allowing the annealing light to pass through, and the annealing light passing through the pattern opening is used for annealing a partial area of the wafer. Thus, the light from the light source can selectively pass through the mask layer to reach the platform, and the pattern of the pattern opening can define an effective area of annealing treatment so as to control the formation of corresponding structural pattern in the wafer on the platform, thus the process of defining pattern structures through photolithography process can be eliminated, which can save process steps and significantly reduce costs.

In order to make above purposes, features and beneficial effects of the present disclosure more obvious and understandable, specific embodiments of the present disclosure will be described in detail with the attached drawings.

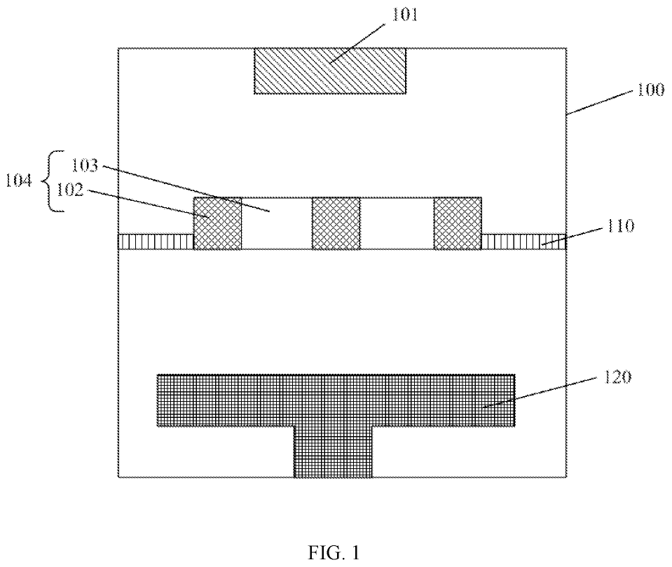

FIG. 1 is a schematic structural sectional view of an optical annealing apparatus according to an embodiment of the present disclosure.

Referring to FIG. 1, the optical annealing apparatus includes a platform 120 for carrying a wafer, a light source 101 for emitting an annealing light to the wafer, and a mask layer 104 disposed between the platform 120 and the light source 101. The mask layer 104 has a pattern opening 103 for allowing the annealing light to pass through, and the annealing light passing through the pattern opening 103 is used for annealing a partial area of the wafer.

In some embodiments, the function of the optical annealing apparatus is to anneal a partial area of the wafer during forming the ion doped region so as to form a patterned ion doped region.

In some embodiments, the optical annealing apparatus further includes a cavity 100 for carrying the light source 101, the mask layer 104 and the platform 120 so as to provide a process platform for annealing process of the wafer.

In some embodiments, the mask layer 104 includes a mask substrate (not shown in the figures) and a plurality of mask pattern structures 102 disposed on the mask substrate. The pattern opening 103 is formed between the plurality of mask pattern structures 102. The material of the mask substrate includes a light transmitting material, and the material of the plurality of mask pattern structures 102 includes an opaque material, thus areas that do not require annealing treatment are blocked. In some embodiments, one pattern opening 103 is formed between two adjacent mask pattern structures 102.

Due to the presence of the mask layer 104, the light from the light source 101 can selectively pass through the mask layer 104 to reach the platform 120, and the pattern of the pattern opening 103 can define an effective area of annealing treatment so as to control the formation of the ion doped region in the wafer on the platform 120. Moreover, since the optical annealing apparatus can control the formation of the ion doped region in the wafer on the platform 12 through the mask layer 104, the process of defining pattern structures through photolithography process can be eliminated, which can save process steps and significantly reduce costs. In addition, since the effective area of the annealing treatment can be controlled through the pattern opening 103 of the mask layer 104, other areas of the wafer that do not require annealing treatment are blocked by the plurality of mask pattern structures 102. Therefore, there is no need to adjust the light source 101 to ensure annealing uniformity on each area of the wafer, which can simplify an adjustment process for adjusting the light source 101 during the annealing treatment process and reduce the process difficulty.

In some embodiments, the pattern opening 103 in the mask layer 104 exposes the mask substrate so as to allow the annealing light emitted by the light source 101 to pass through.

In some embodiments, the annealing light emitted by the light source 101 includes laser.

In some embodiments, by selecting a suitable material for the mask substrate and adjusting a wavelength of the laser emitted by the light source 101, the laser can pass through the pattern opening 103 and the mask substrate.

In some embodiments, the laser has a wavelength ranging from 300 microns to 600 microns.

In some embodiments, in the mask layer 104, the material of the mask substrate includes quartz, and the material of the mask pattern structures 102 includes one or more selected from a group consisting of chromium, molybdenum, selenium, silicon, aluminum and copper.

In other embodiments, the material of the mask substrate may also include other light transmitting materials, and the material of the mask pattern structures may also include other opaque materials. The wavelength of the laser may be greater than 600 microns or less than 300 microns. The material of the mask substrate can allow the laser having corresponding wavelength to pass through the pattern opening and the mask substrate, and the material of the mask pattern structures can block the laser having corresponding wavelength from passing through.

In some embodiments, the optical annealing apparatus further includes an optical system for adjusting and controlling parameters of the light source 101. The optical system is arranged in the light source 101.

In some embodiments, the optical annealing apparatus further includes a transporting system. The transporting system can transport the wafer to the platform 120 or transport the wafer from the platform 120. The transporting system is connected with the platform 120.

In some embodiments, the optical annealing apparatus further includes a mask carrying component 110 for adjusting a relative position between the mask layer 104 and the wafer. The mask carrying component 110 ensures that the position of the mask layer 104 is aligned with the wafer, thereby ensuring that the pattern of the pattern opening 103 in the mask layer 104 corresponds to a corresponding area of the wafer.

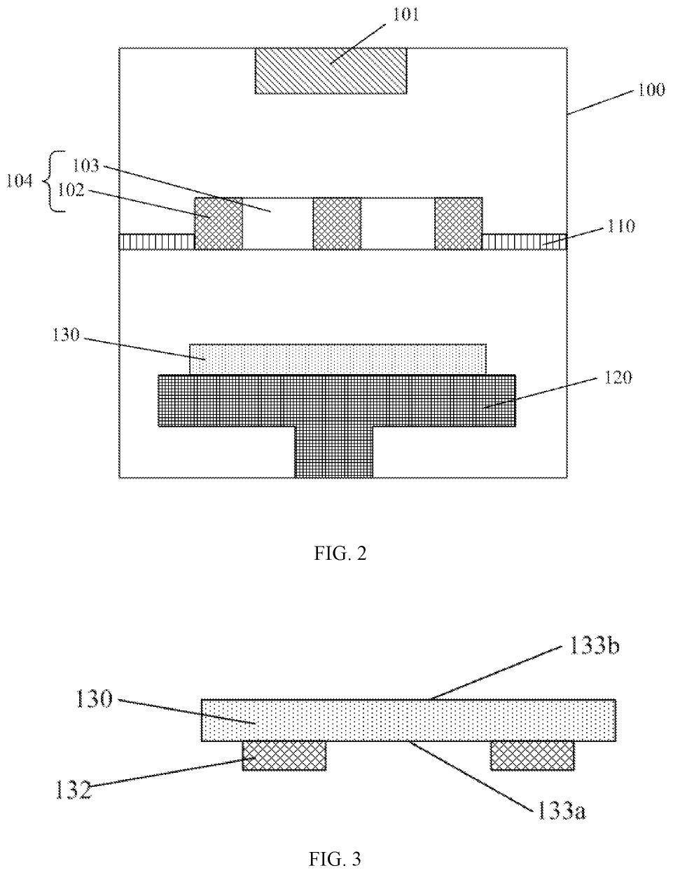

FIGS. 2 to 5 are schematic structural sectional views illustrating steps of a method for forming a semiconductor structure according to an embodiment of the present disclosure.

Referring to FIGS. 2 and 3, FIG. 3 is an enlarged view of a wafer 130 in FIG. 2. The method includes: providing an optical annealing apparatus, wherein the optical annealing apparatus includes: the platform 120 for carrying the wafer; the light source 101 for emitting the annealing light to the wafer 130; and the mask layer 104 disposed between the platform 120 and the light source 101; providing the wafer 130; placing the wafer 130 on the platform 120. The mask layer 104 has the pattern opening 103 for allowing the annealing light to pass through, and the annealing light passing through the pattern opening 103 is used for annealing a partial area of the wafer 130.

In some embodiments, the specific structure of the optical annealing apparatus is shown in FIG. 1 and will not be further described here.

In some embodiments, the wafer 130 has a thickness ranging from 50 microns to 200 microns.

In some embodiments, the wafer 130 has a first surface 133a and a second surface 133b opposite to each other. The first surface 133a has a first device region 132, and the second surface 133b faces the light source 101. Therefore, in the method for forming the semiconductor structure according to the embodiments of the present disclosure, a back side of the wafer 130 is annealed using the optical annealing apparatus to form a back side device region (not shown).

In other embodiments, neither side of the wafer has a device region, and either side of the wafer can be annealed using the optical annealing apparatus.

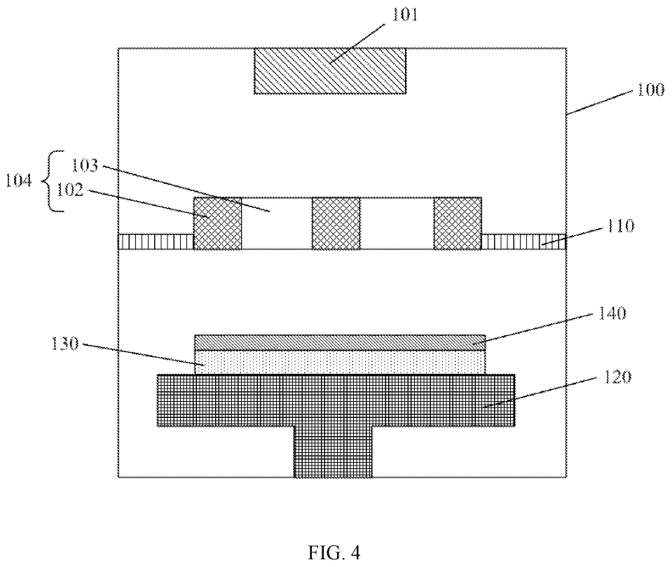

Referring to FIG. 4, an ion implantation is performed on the wafer 130, and an initial ion implantation region 140 is formed in the wafer 130.

In some embodiments, the initial ion implantation region 140 provides raw materials for subsequently formed ion doped region, and after annealing treatment, an ion doped region is formed in a partial area of the initial ion implantation region 140.

In some embodiments, due to the subsequent control of the mask layer 104 of the optical annealing apparatus, a partial annealing treatment can be performed on a partial area of the initial ion implantation region 140. Therefore, the ion implantation can be performed on all areas of the surface of the wafer 130 to form the initial ion implantation region 140, which can expand the window of the ion implantation process.

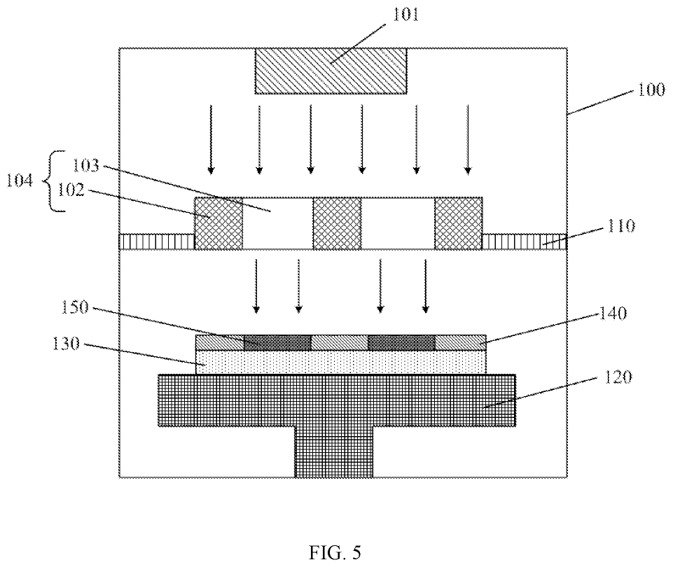

Referring to FIG. 5, an annealing treatment is performed on a portion of the initial ion implantation region 140 using the optical annealing apparatus to form an ion doped region 150 in the portion of the initial ion implantation region 140.

In some embodiments, the mask layer 104 includes a mask substrate (not shown in the figures) and a plurality of mask pattern structures 102 disposed on the mask substrate. The pattern opening 103 is formed between the plurality of mask pattern structures 102. The material of the mask substrate includes a light transmitting material, and the material of the plurality of mask pattern structures 102 includes an opaque material, thus areas that do not require annealing treatment are blocked. Therefore, the pattern opening 103 can define an effective area of annealing treatment in the initial ion implantation region 140 by controlling the area through which the annealing light emitted by the light source 101 passes through, and can then activate ions in a specific area of the initial ion implantation region 140, so as to control the formation of the ion doped region 150 in the corresponding area of the wafer 130.

In some embodiments, the mask layer 104 can control the specific area of annealing treatment on the wafer 130, and the pattern of the pattern opening 103 in the mask layer 104 corresponds to the pattern of the ion doped region 150. Before and during the annealing treatment, the mask carrying component 110 ensures that the position of the mask layer 104 is aligned with the wafer 130, thereby ensuring that the pattern of the pattern opening 103 in the mask layer 104 corresponds to the corresponding area of the wafer 130, so as to ensure that a size and position of the pattern of the ion doped zone 150 meet design expectation.

During the annealing treatment, the light source 101 emits annealing light, and the annealing light passes through the pattern opening 103 and the mask substrate in the mask layer 104 to reach the initial ion implantation region 140 on the second surface 133b of the wafer 130, so as to perform annealing treatment on a portion of the initial ion implantation region 140 corresponding to the pattern opening 103, activating the ions therein to form the corresponding ion doped region 150.

In some embodiments, due to the blocking of the mask pattern structures 102 in the mask layer 104, the portion of the initial ion implantation region 140 is not affected by the annealing treatment. Therefore, the ions in the corresponding region are not activated, so that these inactive ions have no effect on the overall electrical performance of the semiconductor structure.

Due to the presence of the mask layer 104, the light from the light source 101 can selectively pass through the mask layer 104 to reach the wafer 130 on the platform 120, and the pattern of the pattern opening 103 can define an effective area of annealing treatment so as to control the pattern of the ion doped region 150 in the wafer 130. Moreover, since the mask layer 104 can control the light from the light source 101 to selectively pass through the mask layer so as to control the pattern of the ion doped region 150, the process of defining the pattern of the ion doped region 150 through photolithography process in traditional ion implantation processes can be eliminated, which can save process steps and significantly reduce process costs, especially reduce process costs in forming a photolithography pattern layer on the back side of ultra-thin wafer 130, and expand the window of ion implantation process during the formation of the initial ion implantation region 140.

In addition, since the effective area of the annealing treatment can be controlled through the pattern opening 103 of the mask layer 104, other areas of the wafer 30 that do not require annealing treatment are blocked by the plurality of mask pattern structures 102. Therefore, the light source 101 can emit annealing light according to the conditions of comprehensive annealing treatment, and there is no need to adjust the light source 101 to ensure annealing uniformity on each area of the wafer, which can simplify an adjustment process for adjusting the light source 101 during the annealing treatment process, reduce the process difficulty and reduce the process time.

In some embodiments, the process of forming the initial ion doped region 140 is performed on the platform 120 of the optical annealing apparatus.

In other embodiments, the process of forming the initial ion doped region can be performed outside the optical annealing apparatus. After forming the initial ion doped region on the wafer, the wafer is placed on the platform of the optical annealing apparatus for subsequent annealing treatment.

Although the present disclosure has been disclosed above, the present disclosure is not limited thereto. Any changes and modifications may be made by those skilled in the art without departing from the spirit and scope of the present disclosure, and the scope of the present disclosure should be determined by the appended claims.

1. An optical annealing apparatus, comprising:
a platform for carrying a wafer;
a light source for emitting an annealing light to the wafer; and
a mask layer disposed between the platform and the light source, wherein the mask layer has a pattern opening for allowing the annealing light to pass through, and the annealing light passing through the pattern opening is used for annealing a partial area of the wafer.

2. The optical annealing apparatus according to claim 1, wherein the annealing light emitted by the light source comprises laser.

3. The optical annealing apparatus according to claim 2, wherein the laser has a wavelength ranging from 300 microns to 600 microns.

4. The optical annealing apparatus according to claim 1, wherein the mask layer comprises a mask substrate and a plurality of mask pattern structures disposed on the mask substrate, and the pattern opening is formed between the plurality of mask pattern structures, wherein the mask substrate is made of a light transmitting material, and the plurality of mask pattern structures are made of an opaque material.

5. The optical annealing apparatus according to claim 4, wherein the mask substrate is made of quartz.

6. The optical annealing apparatus according to claim 4, wherein the plurality of mask pattern structures are made of one or more selected from a group consisting of chromium, molybdenum, selenium, silicon, aluminum and copper.

7. The optical annealing apparatus according to claim 1, further comprising an optical system for adjusting and controlling parameters of the light source.

8. The optical annealing apparatus according to claim 1, further comprising a transporting system for transporting the wafer to the platform or transporting the wafer from the platform.

9. The optical annealing apparatus according to claim 1, further comprising a mask carrying component for adjusting a relative position between the mask layer and the wafer.

10. A method for forming a semiconductor structure, comprising:
providing an optical annealing apparatus, wherein the optical annealing apparatus comprises: a platform for carrying a wafer; a light source for emitting an annealing light to the wafer; and a mask layer disposed between the platform and the light source, wherein the mask layer has a pattern opening for allowing the annealing light to pass through, and the annealing light passing through the pattern opening is used for annealing a partial area of the wafer;
providing the wafer;
placing the wafer on the platform;
performing an ion implantation on the wafer to form an initial ion implantation region in the wafer; and
annealing a portion of the initial ion implantation region to form an ion doped region in the portion of the initial ion implantation region by the optical annealing apparatus.

11. The method according to claim 10, wherein the wafer has a thickness ranging from 50 microns to 200 microns.

12. The method according to claim 10, wherein the pattern opening has a pattern corresponding to a pattern of the ion doped region.

13. The method according to claim 10, wherein the wafer has a first surface and a second surface opposite to each other, the first surface has a first device region, and the second surface faces the light source.
